(19) United States
(12) Patent Application Publication
(10) Pub. No.: US 2026/0029484 A1
(43) Pub. Date: Jan. 29, 2026

(54) A METHOD FOR CHARACTERIZING THE EVOLUTION OF STATE OF HEALTH OF A DEVICE WITH DURATION OF OPERATION

(71) Applicants: TotalEnergies OneTech, Courbevoie (FR); Université de Lorraine, Nancy (FR); CENTRE NATIONAL DE LA RECHERCHE SCIENTIFIQUE, Paris (FR)

(72) Inventors: Benjamin Larvaron, Kremlin Bicetre (FR); Antoine Bertoncello, Marnes-La-Coquette (FR); Marianne Clausel, Nancy (FR); Sébastien Benjamin, Leognan (FR); Georges Oppenheim, Paris (FR)

(21) Appl. No.: 18/998,962

(22) PCT Filed: Jul. 27, 2023
(86) PCT No.: PCT/EP2023/070831

§ 371 Date: Jan. 27, 2025

(30) Foreign Application Priority Data
Jul. 28, 2022 (EP) 22306133.4

(51) Int. Cl. G01R 31/392; G01R 31/367

(52) U.S. Cl. CPC G01R 31/392; G01R 31/367

(57) ABSTRACT

A computer-implemented method for characterizing an evolution of the state of health of a population of devices with duration of operation comprises training a model on a database comprising, for each device among the population of devices, a value of duration of operation of the device and a corresponding state of health of the device, said model being a random process comprising at least a sum of: a term representing an average evolution of the state of health of the population of devices with duration of operation, and a term representing an inter-device variability of a degradation of the state of health at equal duration of operation, the variance of said term evolving with the duration of operation.

### BACKGROUND

### Technical Field

The present disclosure relates to a method for characterizing the evolution of a state of health of a population of devices according to duration of operation. The present disclosure can be applied in particular to a prediction of the state of health of batteries and fuel cells.

### Description of the Related Art

Important efforts are made to find alternatives to fossil energies. These alternatives increase considerably the use of electrical energy, with an increased need of storage of electricity and of alternative modes of production of electricity.

Regarding storage of electricity, batteries, in particular lithium-ion batteries, are a preferred solution for many applications, due to their falling costs and high physical performance: high energy efficiency, long cycle life, high energy density, and high power density.

Regarding alternative modes of production of electricity, hydrogen fuel cells are considered as a very promising in particular in the field of transports.

A limiting aspect of electrical batteries and fuel cells is that they age with time. Depending on their composition and conditions of use, their performance degrade until they are considered unfit for their designed use. This time corresponds to their lifetime.

For manufacturers and operators, knowledge of the aging process is a major issue to determine the optimal duration of operation for a given model and plan maintenance or replacement operations.

Regarding the case of batteries, to quantify the aging behavior of a new kind of battery, manufacturers perform a series of aging tests in controlled experimental conditions on a batch of batteries. The degradation is quantified thanks to state of health indicators such as capacity or internal resistance. However, these tests are expensive and time consuming, so generally, only few batteries are tested. The data is then used to model the typical evolution with duration of operation of the state of health.

However, such modelling requires to account for the variability of the phenomenon of degradation of the health of state with time, because it enables determining the extreme ageing cases that are quicker or slower than average. With reference to FIG. 1, representing capacity measurements for 47 batteries, considering a batch of batteries with similar design and cycled at identical conditions, an important range of state of health may be observed after a fixed time. FIG. 1 represents the capacity C of a battery as a function of a number of cycles NC. As can be seen in the figure, the uncertainty increases with time, since at cycle 100 it is approximatively of 1% of the nominal capacity, whereas at cycle 1300 it is close to 20%.

It is thus needed to model accurately this variability of the evolution of the state of health. The same considerations apply for fuel cells.

It is known for instance from:
R. Richardson et al, “Gaussian Process Regression for forecasting battery state of health,” in Journal of Power Sources, 357:209-219, 2017, and
D. Liu et al, “Prognostics for state of health estimation of lithium-ion batteries based on combination gaussian processes functional regression,” in Microelectronics Reliability, 53(6):832-839, 2013,
methods for predicting the future capacity of a battery, by application of Gaussian process regressions.

However, the models that are relied upon in these articles rely on stationarity assumptions and do not accurately account for the evolution with time of the inter-battery variability in capacity.

### BRIEF SUMMARY

In view of the above, the present disclosure aims at proposing a method for characterizing an evolution of the state of health of a device with duration of operation, that accurately renders the evolution with duration of operation of the inter-device variability in state of health.

Another aim of the disclosure is to provide an interpretable model in which the different sources of uncertainty are decomposed.

Accordingly, a computer-implemented method for characterizing the evolution of the state of health of a population of devices with duration of operation, the method comprising training a model on a database comprising, for each device among the population of devices, a value of duration of operation of the device and a corresponding state of health of the device, said model being a random process comprising at least a sum of:
a term representing an average evolution of the state of health of the population of devices with duration of operation, and
a term representing an inter-device variability of a degradation of the state of health at equal duration of operation, the variance of said term evolving with the duration of operation.

In embodiments, the method further comprises inferring, from said training, a mean value and associated uncertainty of the state of health of devices of the population, for at least one duration of operation.

In embodiments, the term representing the average evolution of the quantity with duration of exploitation is a Gaussian process.

In embodiments, the term of a regression function representing inter-device variability is a non-linear combination of random processes.

In embodiments, the term of a regression function representing inter-device variability is a non-linear combination of Gaussian Processes.

In embodiments, the term of a regression function representing inter-device variability is a product of:
a first Gaussian Process, corresponding to a deviation of the predicted quantity from the average, said first Gaussian Process having constant variance with duration of operation, and
a positive transform of a second Gaussian Process, corresponding to the evolution of the deviation with duration of operation.

In embodiments, the model is approximated by variational inference.

In embodiments, said training comprises adding to the database data representative of the tendency, with duration of operation, of at least one term of the model.

In embodiments, said training comprises adding to the database data representative of the monotony or concavity, with duration of operation, of at least one term of the model.

In embodiments, the database comprises, for the population of devices, values of state of health corresponding to values of duration of operation that are below a maximum duration of operation, and the method further comprises inferring, from said training, a mean value and associated uncertainty of the state of health of devices of the population, for at least one duration of operation exceeding said maximum duration of operation.

According to another object, it is disclosed a computer-implemented method for characterizing the evolution of the state of health of a population of devices with duration of operation and according to determined operational conditions, comprising:
implementing the method according to the description above at least two times and under at least two respective different operational conditions, to obtain respectively at least two trained models corresponding to each operational condition,
computing, from the trained models corresponding to the at least two different operational conditions, a prediction model configured to predict a model characterizing the evolution of the state of health of a population of devices with duration of operation, for a plurality of additional operational conditions, and
implementing the prediction model to obtain at least an additional predicted model characterizing the evolution of the state of health of a population of devices with duration of operation, for at least one additional operational condition.

In embodiments, the operational condition is defined by a fixed value of at least one operational factor.

In embodiments, the operational factor comprises a temperature of operation.

In embodiments, the device is a battery and the operational factor comprises at least one of a charge cutoff current, a charging rate, a discharging rate, a depth of discharge, or a current at which the constant voltage (CV) phase of a constant current-constant voltage (CC-CV) charge is stopped.

In embodiments, the prediction model is a conditional Wasserstein barycenter having coordinates that are the values of a function of the operational conditions.

In embodiments, the prediction model is a Fréchet regression.

In embodiments, the at least two different operational conditions correspond to different values of a single operational factor, and computing the prediction model comprises determining the function of the operational conditions by defining said function as a parametric function depending on a parameter that is learned on a database formed by a plurality of pairs comprising an operational condition and a trained model corresponding to that operational condition.

In embodiments, the methods presented above further comprise determining, from the trained model, an expected lifetime of a device of a same model that the devices of the population.

In embodiments, the method further comprises determining, from the trained model, for a device belonging to the population, a value of state of health and associated uncertainty for a given duration of operation of the device.

In embodiments, the method further comprises inferring from the mean value of state of health and associated uncertainty for a given duration of operation of the device, and from an expected lifetime of the model of device, a remaining useful life of the device and associated uncertainty.

In embodiments, the methods further comprise determining, from a trained model or a predicted model, and from data associated to a device comprising, for at least one duration of operation, a state of health of the device, a deviation of the device from the predicted mean trend of the population and inferring, from said deviation, at least one prediction of the evolution of the state of health of the device for at least one respective future duration of operation of the device.

In embodiments, the device is a battery or a fuel cell.

Also disclosed herein is a computer-program product comprising code instructions for implementing the method according to the above description, when it is implemented by a computer.

Also disclosed herein is a non-transitory computer-readable storage medium having stored thereon a computer program comprising instructions, the computer program being loadable into a processor and adapted to cause the processor to carry out, when the computer program is run by the processor, the method according to the above description.

Also disclosed herein is a device for predicting the state of health of a battery, comprising a computer and a memory, the device being configured for implementing the method according to the above description.

Also disclosed herein is a distributed computing system comprising a server storing a model trained by implementation of the method according to the description above, and a battery management system or a fuel cell management system, wherein the battery management system or fuel cell management system is configured to:
receive a duration of operation of a battery or a fuel cell, respectively,
communicate said duration of operation to the server,
and the server is configured to obtain, from said duration of operation and by application of the model, an indicator comprising at least one of a state of health or remaining useful life of the battery or fuel cell, and return said indicator to the battery management or fuel cell management system, respectively.

The disclosed method enables characterizing the evolution of the state of health of a population of device, such as a battery or a fuel cell, taking into account the inter-device variability and the evolution of said variability with the duration of operation. The characterization may be performed over all the trajectory of degradation of state of health of the device. In embodiments, the characterization extends to values of duration of operation that have not been observed in the training database. This spares the need for observations over all possible values of duration of operation, which results in an important gain of time and resources (e.g., in the case of batteries, a number of charges) for gathering the training data.

Characterizing adequately a population of devices enables a better determination of a lifetime of the devices.

The disclosed method can also be applied for predicting a state of health corresponding to a future duration of operation for a device belonging to the population based on which the training has been performed.

### BRIEF DESCRIPTION OF THE SEVERAL VIEWS OF THE DRAWINGS

Other features and advantages of the present disclosure will be apparent from the following detailed description given by way of non-limiting example, with reference to the accompanying drawings, in which:

FIG. 1 represents degradation of the capacity of a population of lithium-ion batteries with the number of cycles of operation,

FIG. 2 displays the predictions of a model according to an embodiment of the present disclosure,

FIG. 3 represents the compared evolution of standard deviation between a model with and without stationary variance, and empirical standard deviation of a population of batteries.

FIGS. 4a and 4b represent the evolution with the number of training devices of mean absolute error (MAE) for prediction models having respectively stationary and non-stationary variances.

FIGS. 5a and 5b represent the evolution with the number of training devices of negative log predictive density (NLPD) for prediction models having respectively stationary and non-stationary variances.

FIGS. 6a and 6b represent the compared prediction of a model according to the first embodiment and a model according to another embodiment, in which the model comprises constraints regarding the second derivative of a term, and the predictions cover a range of durations of operation that is larger than the range of durations of operation observed among the training data.

FIGS. 7a to 7c represent compared MAE values of models as a function of the predictive range in number of cycles of operation, i.e., as a function of the number of cycles of operation for which a prediction is made and that are not observed in the training database.

FIGS. 8a to 8c represent compared NLPD values of models as a function of the predictive range in number of cycles of operation.

FIG. 9 schematically represents a device for predicting a state of health of a target device.

FIGS. 10a and 10b respectively represent experimental degradation curves (datapoints) and learned models (shaded areas) of the capacity of batteries with the number of cycles of operation, for a plurality of temperatures of operation and, for FIG. 10a, for a current charge cutoff of 0.2 C, and, for FIG. 10b, for a current charge cutoff of 0.025 C.

FIGS. 11a and 11b respectively represent prediction models of degradation of the capacity of batteries with the number of cycles of operation and for different values of temperature of operation, by implementation respectively of two embodiments of a method according to the present disclosure.

FIG. 12 schematically represents the main step of a method according to an embodiment of the present disclosure.

### DETAILED DESCRIPTION

Embodiments of methods for characterizing the evolution of the state of health of a population of devices with duration of operation will now be disclosed. The population of devices comprises a plurality of devices of a same model. The devices may be batteries, for instance lithium-ion batteries, or fuel cells, for instance hydrogen fuel cells.

When the devices are batteries, an indicator of the state of health of the device can be a capacity value or an internal resistance value. When the target device is a fuel cell, an indicator of the health of state of the device can be a percentage of loss in a power or voltage generated by the fuel cell with reference to an initial value.

As disclosed in more details below, a method for characterizing the evolution with duration of operation of the state of health of a population of devices comprises training a model configured to predict, for a duration of operation of a device, a state of health of the device.

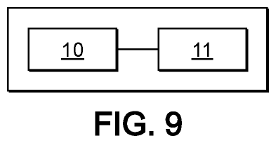

With reference to FIG. 9, the methods described below may be implemented by a computing device 1 comprising a computer 10 and a memory 11. The computer 10 may include one or more processors, microprocessors, microcontrollers, CPUs or GPUs. The memory 11 may be a magnetic hard disk, solid-state disk, optical disk, electronic memory or any type of computer-readable storage medium. The memory stores a computer program, in the form of a set of program-code instructions to be executed by the computer in order to implement all or part of the steps of the method detailed below. The memory 11 may also store the trained model disclosed below.

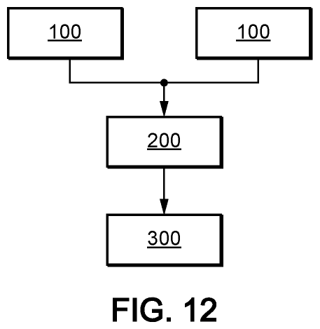

In embodiments where the devices are batteries, the model once trained may be integrated in a battery management system (BMS) and executed by a computing device of the BMS, enabling the BMS to estimate the state of health of the battery and determine continuously the remaining useful life of the battery. In embodiments where the devices are fuel cells, the model once trained may be integrated in a fuel cell management system, and executed by a computing device of the fuel cell management system. In embodiments, the model once trained may be stored in a remote server, remotely accessible by a telecommunication network. For instance, a local computer integrated in a battery of fuel cell management system can send requests to interrogate the model and receive data from a remote computing device storing the model. The same applies to predicted models in accordance with the method described below with reference to FIG. 12.

The duration of operation of the target device may be expressed as a cumulated number of hours of operation of the device, for instance since the manufacturing of the device. Alternatively, in the case of a battery, it may be expressed as a number of cycles of operation, i.e., a number of cycles of charging and discharging the battery. Alternatively, it can also be the cumulative quantity of the capacity that is charged and discharged, also called Ampere hour throughput. When the target device is a fuel cell, the duration of operation may also be expressed as a cumulative electrical energy delivered by the fuel cell, for instance since the manufacturing of the fuel cell.

The method for characterizing the evolution with duration of operation of the state of health of a population of devices comprises training 100 a model on a database comprising, for a population B comprising a plurality of devices of the same type, values t of duration of operation of the devices and corresponding values y of an indicator of state of health of the devices.

By “same type as the target device,” it is meant that all the devices of the database have the same design. For instance, the devices may be of a same make and model, or they may be devices manufactured from a same production batch.

In embodiments, the database comprises, for each device b, a plurality of values t of duration of operation and corresponding values y of an indicator of state of health of the device. In embodiments, for each device, the plurality of values of duration of operation extends from the reference target device being in new condition (i.e., minimum duration of operation) to a duration of operation where the reference target device is no longer fit for use. However, and as will be explained in more details below, this is not necessary and the database may alternatively comprise of state of health of devices corresponding to durations of operation which extend between 0 and a maximum duration of operation which may be less than a duration for which at least one of the devices is no longer fit for use. A device may be considered as being no longer fit for use when its performances are degraded by a predefined quantity, with reference to the performances of the same device in new condition.

In embodiments, the model is a random process, comprising at least a sum of at least one term, being a random process, representing average evolution of the state of health of the population with duration of operation, and at least one term, also being a random process, representing an inter-device variability of the degradation of the state of health, at equal duration of operation.

In what follows, it is noted x=(t,b) where t is the duration of operation of a device, b refers to a device among the population B, and y(t,b) is the value of the indicator of state of health.

According to an example, the model is defined as:

$$y ( t , b ) = μ ( t ) + v ( t , b ) \qquad ( 1 )$$

where μ(t) is the term representing the average evolution of the state of health of the population B, and v(t, b) is the inter-device variability, i.e., the gap between the state of health of a device of the population and the mean, for a given duration of operation, said gap being variable among the population of devices and evolving with duration of operation.

In embodiments, the model may further comprise a term F corresponding to a measurement error, and be a linear combination of the terms, for instance a sum:

$$y ( t , b ) = μ ( t ) + v ( t , b ) + ε \qquad ( 2 )$$

The measurement error may have a Gaussian distribution with null average constant variance ε˜ [symbol] (0, σ_{ε}²) where σ_{ε}² is the value of the constant variance.

The term μ representing the average evolution of the state of health of the population with duration of operation corresponds to the shared trend of state of health degradation with duration of operation. In embodiments, this term may be a Gaussian Process.

A Gaussian process f is a random process defined thanks to a mean function m and a kernel k, corresponding to a covariance function, such that for an input x:

$$m ( x ) = 𝔼 [ f ( x ) ] \qquad ( 3 )$$

where [symbol] is the expected value or mean of the function f, and

$$k ( x , {x}^{′} ) = 𝔼 [ ( f ( x ) - m ( x ) ( f ( {x}^{′} ) - m ( {x}^{′} ) ] ] \qquad ( 4 )$$

Regarding the term representing the average evolution of the state of health of the population with duration of operation, the Gaussian Process may be defined as:

$$μ ∼ 𝒢𝒫 ( {m}_{μ} , {k}_{μ} )$$

where σ_{μ} is the mean function, which can be selected constant and equal to the empirical mean of the training data. The kernel k_{μ} can be chosen as an infinitely derivable function to properly model the degradation trend; for instance a Squared Exponential (SE) model, defined as:

$${k}_{S E} ( x , {x}^{′} ) = {σ}_{μ}^{2} exp ( - \frac{{‖ x - {x}^{′} ‖}^{2}}{2 {l}_{μ}^{2}} ) \qquad ( 5 )$$

where σ_{μ} is the standard deviation modeling the amplitude of the variations of ρ whereas l_{μ} is the length-scale, i.e., a parameter describing the characteristic distance of variations of the function p. Roughly speaking, for two positions x and x′ with a distance superior to l_{μ}, μ(x) and μ(x′) are almost independent, their correlation is close to zero. σ_{μ} and l_{μ} are hyperparameters learnt during training of the function.

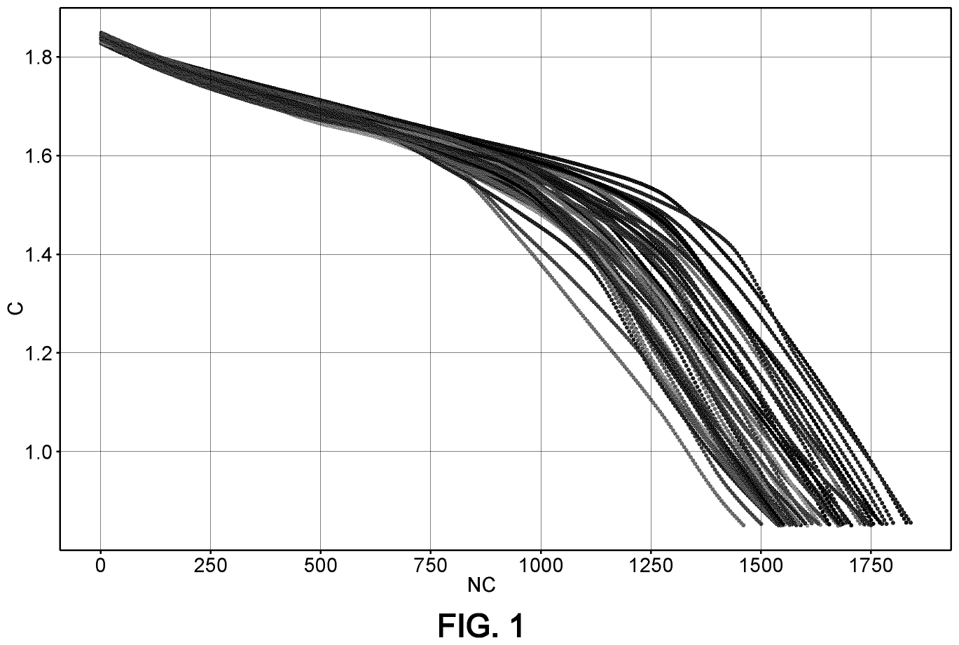

The term representing the inter-device variability of the degradation of the state of health, for equal duration of operation, is non-stationary, because the variance of this term evolves with duration of operation, to account for the growing inter-device variability of the state of health with duration of operation, as visible for instance on FIG. 1.

In embodiments, the term may be a non-linear combination of random processes, for instance a non-linear combination of Gaussian Processes.

According to an embodiment, the term is a product of:
a first Gaussian Process y_{standard}˜ [symbol] (m_{y}, k_{y}), corresponding to a deviation of the predicted quantity from the average, said first Gaussian Process having constant variance with duration of operation, and
a positive random process σ₀, corresponding to the evolution of the standard deviation, and hence of the variance, of the inter-device variability with duration of operation:

$$v ( t , b ) = {σ}_{0} ( t ) \cdot {y}_{standard} ( t , b ) \qquad ( 6 )$$

As σ₀ accounts for the evolution of the standard deviation of the inter-device variability with duration of operation, y_{standard} is constructed so as to have a constant variance with duration of operation, i.e., it is set equal to 1.

Regarding the kernel of y_{standard}, denoted k_{y} we suppose that the deviations of two different devices from the trend of the population, are independent. To impose that, the kernel is chosen such that:

$${k}_{y} ( x , {x}^{′} ) = {\hat{k}}_{y} ( t , {t}^{′} ) I ( b = {b}^{′} ) \qquad ( 7 )$$

with I an indicator function.

Moreover, the kernel can be chosen as being stationary meaning that \hat{k}_{y} (t, t′)=\hat{k}_{y}(t−t′), which is the case of mostly used kernels, and thus having constant variance. Indeed, a consequence of stationarity is that \hat{k}_{y}(t, t)=\hat{k}_{y}(0)=constant, i.e., the variance of the process does not depend on t and is constant. In embodiments, the kernel may be chosen between the two following kernels, since the SE kernel is too smooth to model individual variations of state of health of devices:
Matérn 5/2 kernel defined as:

$${k}_{Ma 52} ( t , {t}^{′} ) = {σ}_{y}^{2} ( 1 + \frac{\sqrt{5} ‖ t - {t}^{′} ‖}{{l}_{y}} + \frac{5 {‖ t - {t}^{′} ‖}^{2}}{3 {l}_{y}^{2}} ) exp ( - \frac{\sqrt{5} ‖ t - {t}^{′} ‖}{{l}_{y}} ) \qquad ( 8 )$$

Matérn 3/2 kernel defined as:

$${k}_{Ma 32} ( t , {t}^{′} ) = {σ}_{y}^{2} ( 1 + \frac{\sqrt{3} ‖ t - {t}^{′} ‖}{{l}_{y}} ) exp ( - \frac{\sqrt{3} ‖ t - {t}^{′} ‖}{{l}_{y}} ) \qquad ( 9 )$$

σ_{y}² is the variance of y_{standard}, it is set equal to 1.

Regarding the mean m_{y}, it is set constant equal to 0.

σ₀ represents evolution with time of inter-device variability and can be defined according to the evolution of inter-device variability that needs to be learnt.

In embodiments, in order to ensure positivity, σ₀ is the combination of a random process and a positive deterministic function applied to the random process. The positive deterministic function may for instance be chosen as exponential or softplus function. The random process may be a Gaussian Process.

Accordingly, σ₀ may for instance be written as:

$${σ}_{0} ( t ) = P ( η ( t ) ) \qquad ( 10$$

where P is the deterministic positive function which may be chosen among the examples given above, and η(t) is a Gaussian Process which can be chosen with a constant mean function m_{η} that is estimated during the training and a kernel that can be chosen for instance as a SE kernel.

Training the model using the database corresponds to determining the hyperparameters of the model, i.e., in the case of a model according to equation (2) above, the parameters m and k that are not already set, for which the posterior law of the terms of the model p(μ, η, y_{standard}|y) best corresponds to the observation of the database, where y=y(X), μ=μ(X), η=η(X) and y_{standard}=y_{standard}(X).

In embodiments, and in particular when the model comprises a non-linear combination of Gaussian Processes, the training comprises approximating the model, by variational inference, i.e., determining a model approximating the posterior law.

Let us rewrite the parameters (μ, η, y_{standard}) from which the model depends as f₁, . . . , f_{C} where C=3. For f_{c}=ƒ_{c}(X) the dependence is described by the likelihood p(y|f₁, . . . f_{c})

Writing θ the concatenation of the functions f_{c}, i.e., (μ, η, y_{standard}), the training comprises computing an approximation of the posterior law p(θ|y). For that, a family of variational distribution is defined and writing q(θ) an element of this distribution, it has to respect the following condition:

$$q ( θ ) = {\prod }_{c = 1}^{C} q ( {f}_{c} )$$

Compared to the exact posteriors p(f_{c}|y) are replaced by q(f_{c}), supposed independent, for which we take q(f_{c})= [symbol] (f_{c}|μ_{c}, S_{c}). These distributions depend on [symbol] which are variational hyperparameters to be optimized.

The variational hyperparameters are determined by minimization of the Kullback-Leibler divergence between the true unknown posterior and its variational approximation, denoted KL(q(θ)∥p(θ|y)).

The minimization of the KL divergence is equivalent to minimizing the evidence lower bound which can be written:

$$ELBO = {𝔼}_{q} [ log p ( y \vert θ ) ] - K L ( q ( θ ) ‖ p ( θ ) )$$

Or in the case of the model of equations (2) and (6) combined:

$$ELBO = {\sum }_{i = 1}^{N} \int q ( μ ) q ( η ) q ( {y}_{standard} ) p ( {y}_{i} \vert {μ}_{i} , {η}_{i} , {y}_{standard , i} ) d μ d η {dy}_{standard} + KL ( q ( μ ) ‖ p ( μ ) + K L ( q ( η ) ‖ p ( η ) + K L ( q ( {y}_{s t a n d a r d} ) ‖ p ( {y}_{s t a n d a r d} )$$

Thus in embodiments the training of the model comprises determining the hyperparameters and variational hyperparameters minimizing the ELBO function above.

Once the model is trained, a mean value of state of health of a device for a given duration of operation and associated uncertainty are obtained. The mean value corresponds to p(t) and the associated uncertainty can correspond to the standard deviation of the model for duration of operation t. An uncertainty range can thus be defined as being centered on the mean value and having a width equal to the standard deviation Alternatively, the uncertainty range can correspond to a range of values of state of health in which a device of a given duration of operation has a determined probability to be, for instance 0.9, or 0.95.

In embodiments, the mean values and associated uncertainty for a plurality of durations of operation may be used to determine an expected lifetime of a device corresponding to the population of devices for which the model has been trained. The expected lifetime can for instance correspond to a duration of operation for which conditions are met regarding the mean value and optionally the uncertainty of the state of health. The expected lifetime also corresponds to a duration of operation that the considered device has a given probability to reach. For example, the expected lifetime can correspond to a duration of operation at which the mean value of state of health drops below a determined threshold (corresponding to a probability of 0.5). An uncertainty on said lifetime can also be determined by determining the values of durations of operation at which the lower and higher ends of the uncertainty range drop below said threshold.

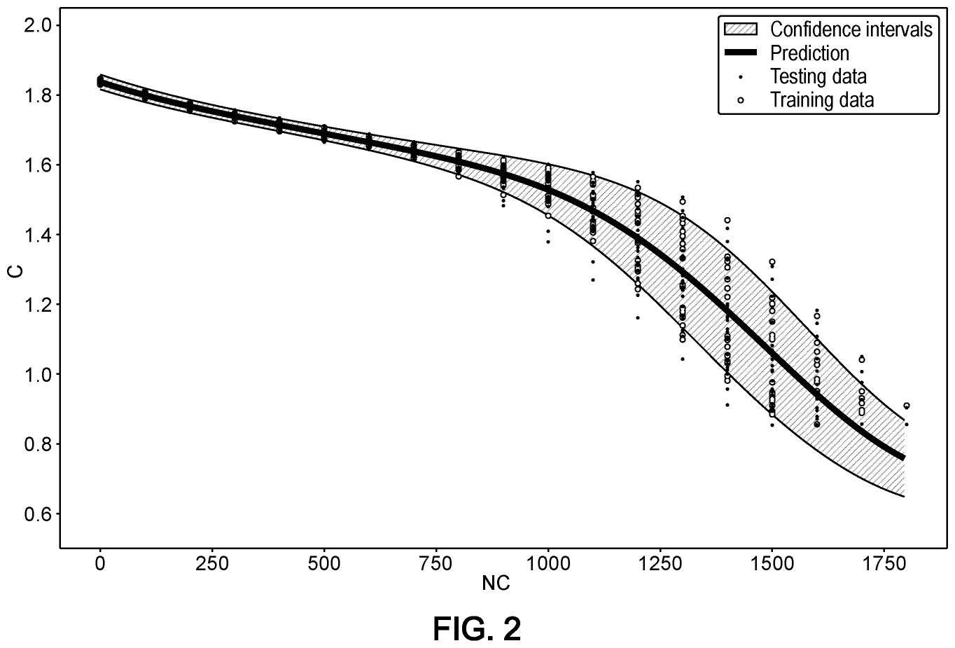

With reference to FIGS. 2 to 5b are shown results obtained with a model trained on a population of lithium-ion batteries, where the regression function is in the form of the following equation:

$$y ( t , b ) = μ ( t ) + P ( η ( t ) ) \cdot {y}_{standard} ( t , b ) + ε \qquad ( 11 )$$

where μ, η and y_{standard} are gaussian processes defined as follows:
m_{μ} is the empirical mean of the training data and kg is a SE kernel,
m_{y} is null and k_{y} is a Matern 3/2 kernel,
m η is a constant function and k η is a SE kernel,
P is an exponential function.

Replacing k_{y} by a Matern 5/2 kernel and P by a softplus transform does not change the results.

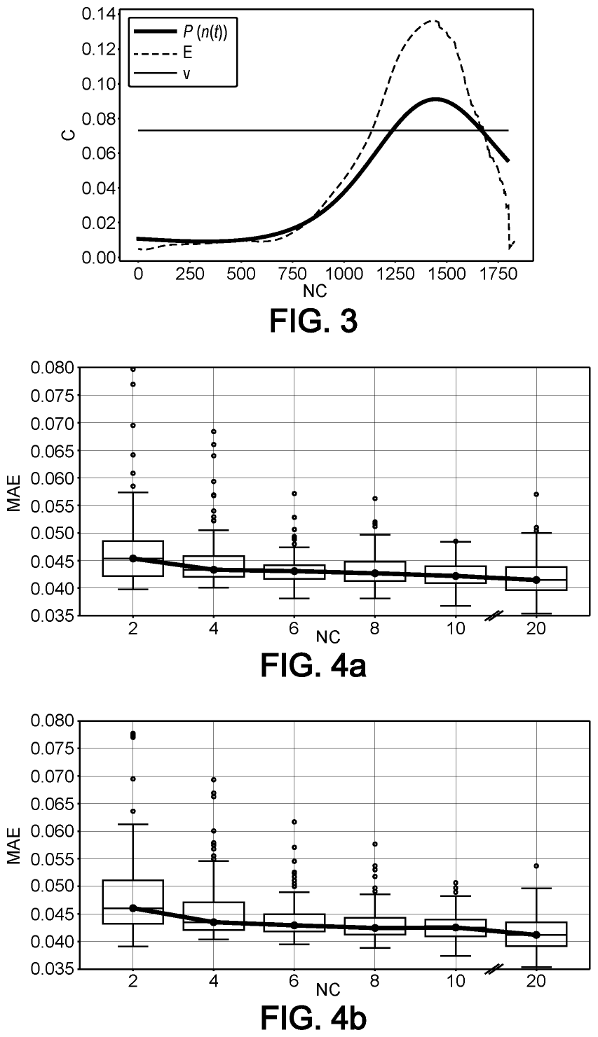

In FIGS. 2 and 3, the duration of operation is expressed in abscissa by a number of cycles NC and the state of health of the batteries is expressed in ordinates by a capacity C.

In FIG. 3 is plotted the evolution of the term (P(η(t))) representing the evolution of the standard deviation of the inter-device variability with duration of operation. In this figure as well, confidence intervals are so narrow that they correspond to the thickness of the line. In comparison is shown the empirical standard deviation E computed on the training dataset (all batteries of the training dataset every 5 cycles). Also, is shown the constant standard deviation of a regression function according to equation 2 above where the term representing inter-device variability v has constant variance. For the 700 first cycles the empirical standard deviation is low and almost constant. The term representing the evolution of the standard deviation of the inter-device variability fits well to the empirical standard deviation while the term of constant standard deviation largely overestimates it. Then around 700 cycles the empirical variance starts to increase quickly. We see a similar behavior for the term P(η(t)) even if it does not increase as fast. After cycle 1100 the term having constant variance seems to underestimate the real variance. So does the term P(η(t)) but the error is smaller.

Complete predictions are shown in FIG. 2. The mean value of the state of health of the population of devices according to the number of cycles NC corresponds to the thick line, and the associated uncertainty corresponds to the confidence interval. The predicted trend fits well the training and testing data, and one can notice that the confidence intervals are much thinner on first cycles than on later cycles (NC>700 in this example), which fits well the evolution of inter-device variability.

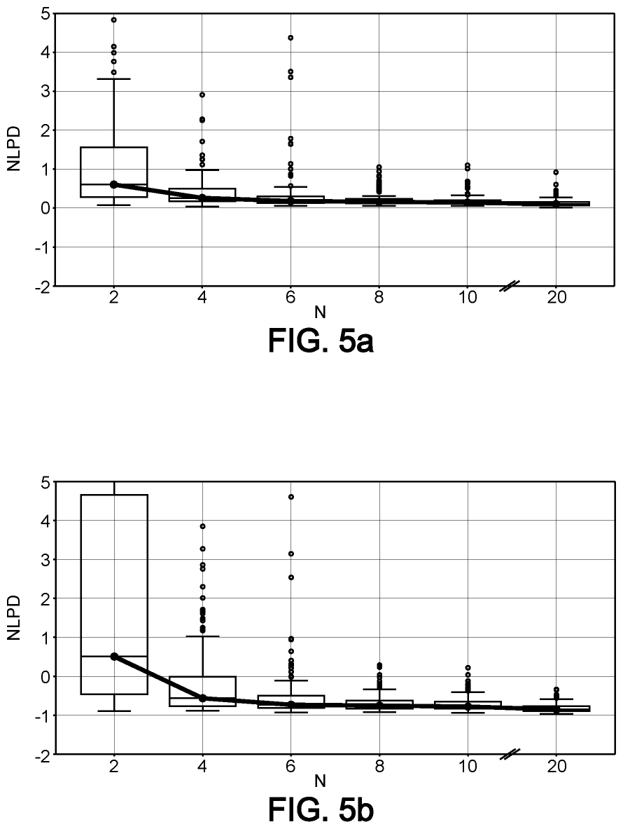

With reference to FIGS. 4a and 4b and 5a and 5b are also shown compared quantitative results obtained for a regression function having a term representing inter-device variability with non-constant variance (FIGS. 4b and 5b) and for a regression function with a term representing inter-device variability having a constant variance (FIGS. 4a and 5a).

FIGS. 4a and 4b represent compared values of mean absolute error MAE obtained for the compared trained functions, plotted against the number of training devices N.

MAE is defined as follows:

$$M A E = \frac{1}{{n}_{test}} {\sum }_{i = 1}^{{n}_{t e s t}} \vert {y}_{i}^{*} - {\hat{y}}_{i} \vert$$

with nₜₑₛₜ the number of observations in the testing set,

$${y}_{i}^{*}$$

the i-th state of health value, not used to train the model, i.e., not among the training data, and ŷᵢ the prediction.
FIGS. 5a and 5b represent compared values of negative log predictive density NLPD for the compared trained functions, plotted against the number of training devices N.

NLPD is defined as follows:

$$N L P D = - \frac{1}{{n}_{test}} {\sum }_{i = 1}^{{n}_{t e s t}} log p ( {y}_{i}^{*} \vert {x}_{i} )$$

where

$${y}_{i}^{*}$$

is the predicted density of y at input xᵢ. As MAE, it is sensitive to errors in mean prediction but at the same time it penalizes under or overestimated uncertainties. It has to be as small as possible.

The indicators MAE and NLPD were computed a hundred times with randomly selected training devices, and each time the fitted function was then tested on the remaining devices. These indicators were computed for six functions including four functions with a term representing inter-device variability with non-constant variance and two with a term representing inter-device variability with constant variance.

Regarding the latter, the term representing inter-device variability with constant variance was a Gaussian Process with either a Matern 3/2 or Matern 5/2 kernel. The function with a term representing inter-device variability with non-constant variance were according to equation 11 in which η had either a Matern 3/2 or Matern 5/2 kernel and the positive function was either the exponential function of softplus function. The differences due to the choice of the kernel or the positive function were small as compared to the differenced between the function in which the inter-device variability had constant or non-constant variance. FIGS. 4a to 5b are plotted for models having Matern 3/2 kernel and exponential positive transform.

Regarding mean predictions (MAE), no major difference can be observed between function with and without an inter-device variability term having constant variance (FIGS. 4a and 5b). However, regarding uncertainties, it can be noticed that NLPD decreases with the number of batteries with a function having an inter-device variability term of constant variance, but remains above zero. When a model having an inter-device variability term of non-constant variance is used, the value of NLPD reaches a significantly lower value, close to −1, and improves quickly to give reasonable performance even with few batteries.

It thus confirms that the use of a heteroscedastic model (i.e., having non constant variance) improves the predicted uncertainties while keeping similar performance than homoscedastic models for mean prediction.

In embodiments, when the model comprises a non-linear combination of Gaussian Processes, and in particular when the model is according to equation (2) with v according to equation (6) above, the training comprises adding to the database data corresponding to prior knowledge of the tendency of at least one term of the model with duration of operation of the devices, and in particular data representative of the monotony or concavity, i.e., of the first or second derivative, respectively, of at least one term of the model. The prior knowledge can for instance be obtained from previously performed tests or can be derived from the knowledge of physical and/or chemical phenomena involved with the operation of the device.

For instance, the mean μ state of health of a battery is known in most settings to be monotonic, i.e.,

$$\frac{d μ}{dt}$$

having a fixed sign, that is decreasing when the indicator of state of health is capacity, or increasing when said indicator is the internal resistance. Moreover, an acceleration of health degradation is often observed after a certain time, which corresponds to prior knowledge on

$$\frac{{d}^{2} μ}{{dt}^{2}} .$$

Prior knowledge is also available for inter-batteries variability σ₀ because the initial state of health is often identical or nearly identical for a population of batteries, but progressively differentiates, which corresponds to an increase of σ₀.

The prior knowledge on the tendency of a component ƒ_{d} may be taken into account by adding, to the database, virtual observations z^{v} taking values in {0,1}depending on the monotony (first derivative) or the concavity (second derivative) of ƒ_{d}.

According to a non-limiting example, let us denote

$${f}_{d}^{′} = \frac{\partial {f}_{d}}{\partial t}$$

the first derivative of a component ƒ_{d} of the model, which may be equal for instance to μ, η (when σ₀=P(η)), or y_{standard}, The virtual observations may be equal to 0 if ƒ_{d} is decreasing, and 1 if ƒ_{d} is increasing.

To integrate them in the model it is supposed that

$${z}_{i}^{v} \vert {f}_{d , i}^{′} ∼ ℬ ( s ( {f}_{d , i}^{′} ) )$$

where B is the Bernoulli distribution, ƒ′_{d}=ƒ′_{d}(X^{v}), and s may be a sigmoid function for a mapping from R to [0,1], a logit function or the inverse of the normal cumulative distribution function. Thus if ƒ′_{d} is positive with high probability at some location, a virtual variable at the same location has a high probability of being equal to 1 and conversely. The same applies mutatis mutandis is a second derivative is used instead of a first derivative to add knowledge about concavity.

Including virtual observations, the model has an extended likelihood p(y, z^{v}|f₁, . . . , f_{C}, f′_{d}), using the same notations as above for fᵢ, which can be factorized as follows:

$$p ( y , {z}^{v} \vert {f}_{1} , … , {f}_{C} , {f}_{d}^{′} ) = {\prod }_{i = 1}^{N} p ( {y}_{i} \vert {f}_{1 , i} , … , f ) {\prod }_{j = 1}^{{N}^{v}} p ( {z}_{j}^{v} \vert {f}_{dj}^{′} )$$

Taking into account the additional parameter f′_{d}, the variational distribution presented above is updated as follows, keeping the same variational hyperparameters:

$$q ( θ ) = p ( {f}_{d}^{′} \vert {f}_{d} ) {\prod }_{c = 1}^{C} q ( {f}_{c} )$$

The updated evidence lower bound, denoted ELBO_{d} becomes:

$${ELBO}_{d} = ELBO + {\sum }_{j = 1}^{{N}^{v}} \int log p ( {z}_{j}^{v} \vert {f}_{dj}^{′} ) q ( {f}_{dj}^{′} ) {d f}_{dj}^{′}$$

with q(f′_{dj})=∫P(f′_{dj}|f_{dj})q(f_{dj})df_{dj}, having an exact analytic equation, using Gaussian properties and the following general properties:

$$Cov [ \frac{\partial f ( t )}{\partial t} , f ( {t}^{′} ) ] = \frac{\partial Cov [ f ( t ) , f ( {t}^{′} ) ]}{\partial t}$$

$$Cov [ \frac{\partial f ( t )}{\partial t} , \frac{\partial f ( {t}^{′} )}{\partial t} ] = \frac{{\partial }^{2} Cov [ f ( t ) , f ( {t}^{′} ) ]}{\partial {t}^{2}}$$

Similar results can be obtained for second order derivative.

In that case, the model improves the predictions of the evolution of state of health of a device for a given duration of operation, even if the duration of operation is not among the observations of the database, or said otherwise, even if duration of operation exceeds the durations of operation for which state of health values are available in the database.

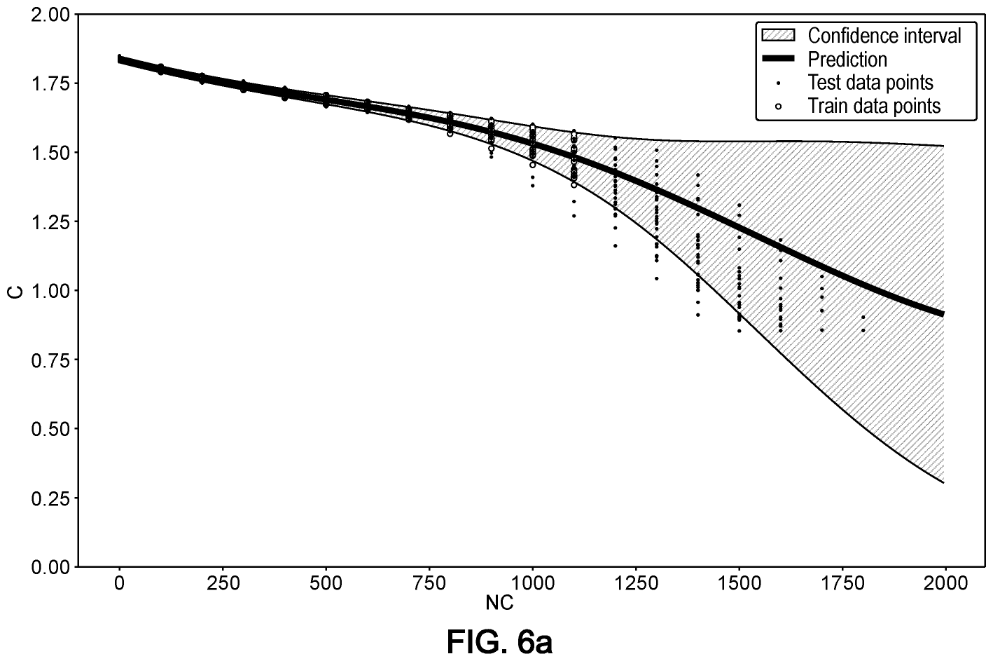

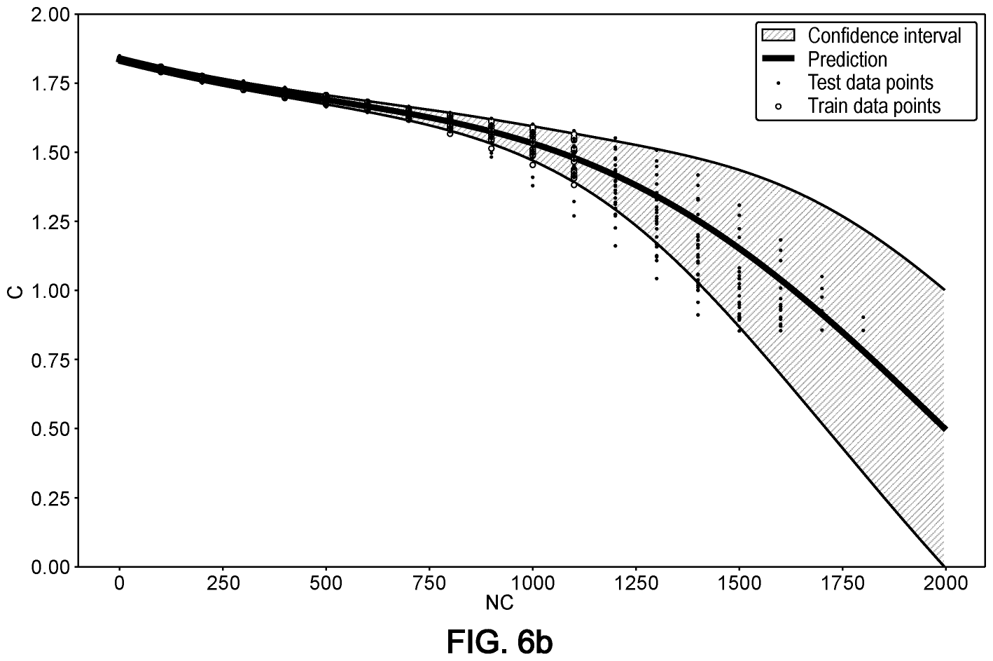

With reference to FIGS. 6a and 6b, are shown compared predictions of models according to equation (11) above, where the predictions extend over durations of operations that are not present in the training database. More specifically, the training database comprised observations until 1100 cycles of observations and the models were applied to predictions until 2000 cycles. In FIG. 6a, no constraint was added to the model regarding the trend of one its terms. In FIG. 6b, a constraint was added to impose negativeness of the second derivative of p after cycle 500 and until cycle 2000, corresponding to an acceleration of the degradation of the state of health. As the trend on the second derivative was well observed on the training data, virtual points were placed only in the forecasting range, i.e., in the range of number of cycles not present in the training data, i.e., between 1100 and 2000 cycles. One point was added every 25 cycles.

One can notice that the mean prediction (thick line) is much more satisfactory with the constrained model than without constraint. After 200 cycles, predicted mean clearly overestimate less testing data. Uncertainty modeling (confidence interval) is also improved with much narrower confidence intervals still including most testing points.

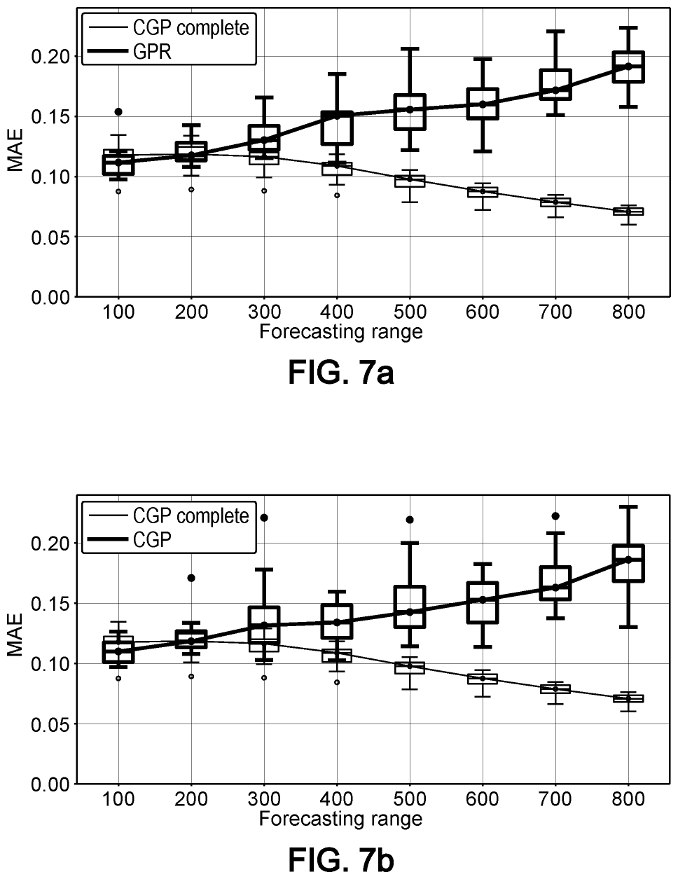

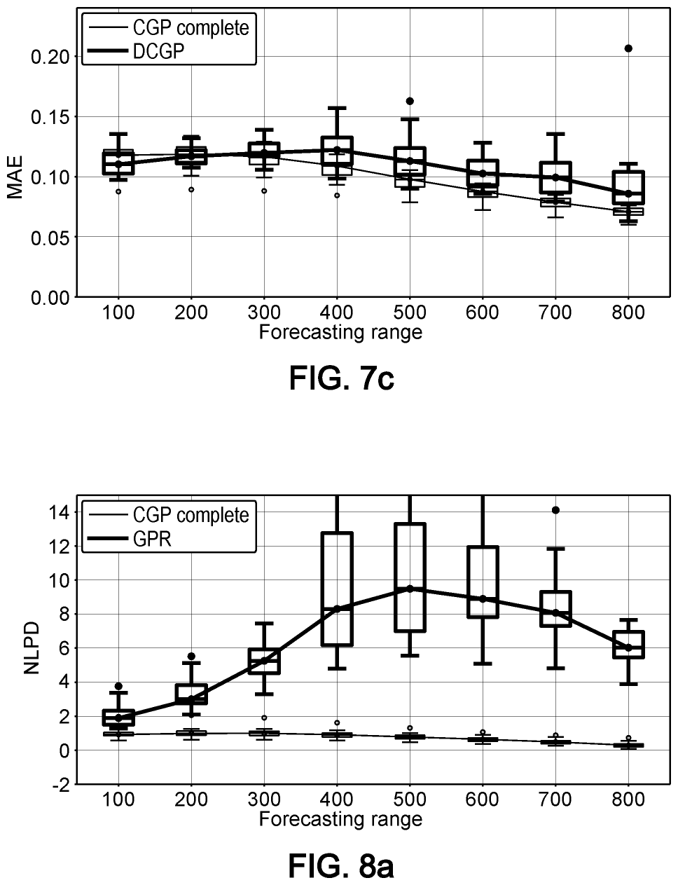

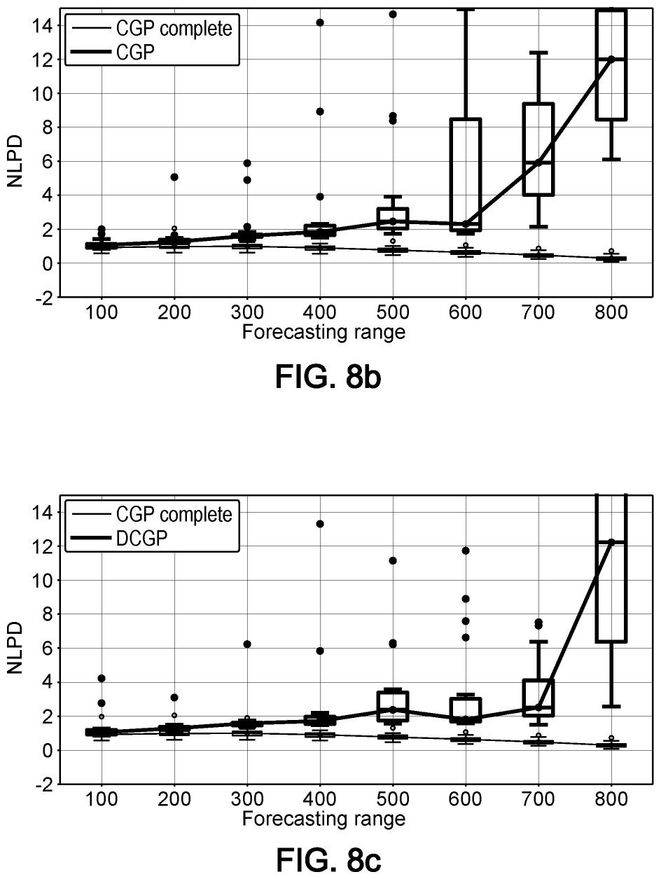

With reference to FIGS. 7a to 7c and 8a to 8c respectively, are also shown the evolution of MAE and NLPD indicators for compared models and as a function of the forecasting range, i.e., the range of duration of operation (in the figures it corresponds to a number of cycles) for which the model is used for prediction and which is not present in the training database.

These indicators MAE and NLPD were considered for cycles up to 1500, with a predictive range of duration of operation between 100 and 800 cycles. That means that compared models are trained on a testing batch of batteries from cycle 0 to cycle 1500 minus the number of cycles corresponding to the predictive range (e.g., 700 when the predictive range is 800), and then they are tested on a testing batch of batteries on cycles 1500 minus the number of cycles corresponding to the predictive range (e.g., 700 when the predictive range is 800) to 1500. The compared models comprise a model according to equation (11) above without constraint, denoted CGP, the same model with second derivative constraint, denoted DCGP, and a Gaussian Process model with squared exponential kernel and constant prior mean equal to the empirical mean of the data, denoted GPR. As a baseline for comparison, a CGP model was also trained on all cycles (denoted CGP Complete in the figures).

It can be noted that both GPR and CGP models have a similar behavior with an error increasing with forecasting range. On the other hand DCGP has a performance much closer to the reference even for a high forecasting range.

Then considering NLPD, it is apparent as in FIGS. 5a and 5b above that the GPR model is not able to anticipate the inter-battery variability increase. Then comparing CGP and DCGP for a forecasting range under 500 cycles observed behavior is qualitatively similar but with small gain with NLPD. However after cycle 500 NLPD increases suddenly for CGP model, which thus reaches its limits. The limit is reached later for the DCGP model, at cycle 800.

Hence it is shown that using constraints on first or second derivatives of some terms of the model enables enhancing the prediction capability of a model, thereby reducing the needs for extensive training database covering the whole possible range of duration of operation of the considered devices.

The method disclosed above allows determining a model of degradation of the state of health with duration of operation for a population of devices with the same conditions of operation.

In what follows, “conditions of operation” or “operational conditions” refer to the values of a set of operational factors which may have an influence on the evolution of the state of health of the devices. In what follows, the value of each operational factor is fixed, i.e., it is considered constant with time, over all the duration of operation of the devices.

For instance, an operating factor may be the temperature of operation.

According to another example, when the devices are batteries, a plurality of operating factors may be defined as: a charge cutoff current, a charging rate, a discharging rate, a depth of discharge, or a current at which the constant voltage (CV) phase of a constant current-constant voltage (CC-CV) charge is stopped.

According to another example, when the devices are fuel cells, operating factors can be the temperature of operation, the load current and humidity.

In embodiments, a method comprises the determination of a model of degradation of the state of health of a population of devices with duration of operation for at least one unobserved operational condition of the devices, i.e., for a condition of operation for which no experimental data is available. Indeed, obtaining data relative to state of health of a plurality of devices, according to duration of operation, and for a large set of different conditions of operation, may be very long and costly.

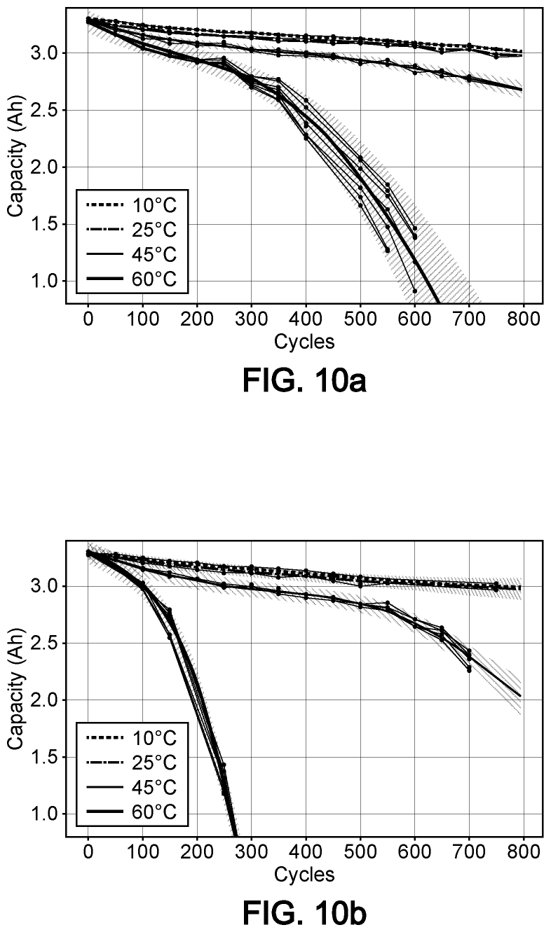

With reference to FIG. 12, such method comprises implementing the method 100 described above, of training a model describing the evolution of the state of health of a population of devices with duration of operation, at least two times, for at least two different operational conditions. For instance, the at least two different operational conditions may be at least two different values of a same operational factor. With reference to FIG. 10a, are shown a plurality of models characterizing the evolution of the capacity of a population of batteries with the number of charging cycles of the batteries, where the models have been trained according to the method 100 above for respectively different values of temperature of operation.

According to another example, the at least two different operational conditions may comprise at least two different values of at least two operational factors. The example represented to FIG. 10a has further been obtained with a constant current charge cutoff value of 0.2 C, while, with reference to FIG. 10b, are shown a plurality of models trained for the same temperatures as FIG. 10a, but for a different current charge cutoff value of 0.025 C.

Therefore, each trained model is fitted independently on each of K different conditions of operations. The predicted curves are discretized at d times until tₘₐₓ resulting in multivariate Gaussian distributions denoted zₖ≈(t [symbol] y_{c}_{ₖ}(t, b*)), with zₖ˜ [symbol] (mₖ, Σₖ) belonging to [symbol] ^{d} the space of Gaussian distributions of such dimension. Each of the zₖ are of the same dimension, meaning that they are all evaluated at the same particular time. In the setting of FIGS. 10a and 10b, tₘₐₓ corresponds to cycle 800.

The method then comprises computing 200, from the trained models obtained for each step 100, and corresponding to different operational conditions, a prediction model which is configured to predict a model characterizing the evolution of the state of health of a population of devices with duration of operation, for a plurality of additional operational conditions. Preferably, each additional operation condition corresponds to an unobserved operational condition, i.e., to an operational condition for which no model has been trained, and for which no data may be available.

This second step thus uses as data

$${( {c}_{k} , {z}_{k} )}_{k = 1}^{K} ,$$

with cₖ, the k-th observed operational conditions as inputs, and zₖ, the k-th trained models corresponding to the observed operational conditions as outputs.

Step 200 comprises building a model that for any c, can predict another model as the trained model described above and obtained by implementing the method 100.

Additionally, it is underlined that when the trained model in step 100 uses the chained Gaussian processes framework, with a nonlinear combination of Gaussian processes components, the predicted model is not exactly a Gaussian distribution. As an approximation, the described methodology presented below is applied independently on each of the Gaussian processes components of the trained models obtained in step 100, obtaining for each one a prediction that is then merged to get the final prediction. Nevertheless, the described approach is directly applicable while using a standard Gaussian processes regression.

The difficulty of this step relies in the complex nature of the zₖ. Denoting ƒ a function that maps an operational condition to a Gaussian distribution, ƒ:C→ [symbol] , where C is the space of operational conditions in [symbol] , p being the number of operational factors, the developments below propose such a ƒ providing suited predictions.

In embodiments, the prediction model for predicting degradation curves with uncertainties is a Wasserstein barycenter.

Considering m distributions αⱼ with coordinates λⱼ such that

$${\sum }_{j}^{m}$$

λⱼ=1, the Wasserstein barycenter is the solution of the following minimization problem (one may also refer to M. Agueh, G. Carlier: “Barycenters in the Wasserstein space,” in SIAM Journal on Mathematical Analysis 43.2 (2011), pp. 904-924):

$$\overline{α} = {arg min}_{α} {\sum }_{j = 1}^{m} {λ}_{j} {𝒲}_{2}^{2} ( {α}_{j} , α ) \qquad ( 12 )$$

where

$${W}_{2}^{2} ( a , β )$$

is the Wasserstein distance between two distributions α and β, solution of the Kantorovitch problem (L. Kantorovitch, “On the transfer of masses,” Doklady Akademii Nauk, 37(2) (1942), pp. 227-229), which corresponds to the minimal total effort of moving the distribution α toward the distribution β on [symbol] , an ifs expressed as follows:

$${W}_{2}^{2} ( α , β ) = {min}_{π ∈ 𝒰 ( α , β )} {\int }_{{ℝ}^{d} \times {ℝ}^{d}} {‖ x - y ‖}_{2}^{2} d π ( x , y ) \qquad ( 13 )$$

By varying the coordinates λⱼ, the Wasserstein barycenter provides an interpolation surface between the different distributions (or interpolating path in case of only two distributions).

In the context of the present disclosure, the prediction model may thus be Wasserstein barycenter expressed as follows:

$$f ( c ) = {\sum }_{j = 1}^{m} {λ}_{j} ( c ) {𝒲}_{2}^{2} ( {z}_{j} , z ) \qquad ( 14 )$$

This prediction model consists in a barycenter of the distributions zⱼ, j comprised between 1 and m, with weighting coefficients depending on the operational condition c. Because of this dependence, the prediction model is called a conditional Wasserstein barycenter. This barycenter is computed between m distributions with m not necessarily equal to K; the more distributions are included in the barycenter, the more flexibility the prediction will have, but with potentially higher risk of overfitting.

In the particular case of Gaussian distributions, explicit solutions exist to the Wasserstein distance and barycenter computation. Given α₀˜ [symbol] (m₀, K₀), and α₁˜ [symbol] (m₁, K₁), the Wasserstein distance is equal to:

$${𝒲}_{2}^{2} ( {α}_{0} , {α}_{1} ) = {‖ {m}_{0} - {m}_{1} ‖}^{2} + tr ( {K}_{0} + {K}_{1} - 2 {( {K}_{0}^{1 / 2} {K}_{1} {K}_{0}^{1 / 2} )}^{1 / 2} ) \qquad ( 15 )$$

Similarly, the barycenter of m Gaussian distributions αⱼ˜ [symbol] (mⱼ, Kⱼ), with coordinates lambda, is a Gaussian distribution α̅˜ [symbol] (m̅, K̅), with

$$\overline{m} = {\sum }_{j = 1}^{m} {λ}_{j} {m}_{j}$$

$$and$$

$$\overline{K} = {\sum }_{j = 1}^{m} {{λ}_{j} ( {\overline{K}}^{1 / 2} {K}_{j} {\overline{K}}^{1 / 2} )}^{1 / 2}$$

The covariance matrix cannot be directly computed from this formula. One should use the converging algorithm presented in P. C. Alvarez-Esteban et al. “A fixed point approach to barycenters in Wasserstein space,” Journal of Mathematical Analysis and Applications 441.2 (2016), pp 744-762.

Starting from an initialization K̅₍₀₎, the following iteration is applied until convergence:

$${\overline{K}}_{( s + 1 )} = {\overline{K}}_{( s )}^{- 1 / 2} ( {\sum }_{j = 1}^{m} {{λ}_{j} ( {\overline{K}}_{( s )}^{1 / 2} {K}_{i} {\overline{K}}_{( s )}^{1 / 2} )}^{2} {\overline{K}}_{( s )}^{- 1 / 2} \qquad ( 16 )$$

As conditional Wasserstein barycenter depends on weighting coefficients which are the values of a function lambda j of the operational conditions, two alternative methods are detailed for specifying these coefficients.

A first approach, hereinafter denoted “structured regression,” is applicable when at least two different operational conditions correspond to different values of a single operational factor. This approach comprises determining the function of the operational conditions by defining said function as a parametric function, and learning said parameter(s) on the pairs

$${( {c}_{k} , {z}_{k} )}_{k = 1}^{K}$$

comprising an operational condition cₖ and a trained model zₖ corresponding to that operational condition.

The λⱼ are thus seen as a parametric function λ_{j,θ}(c) depending on a parameter θ leading to the following prediction model:

$${f}_{θ} ( c ) = {argmin}_{z} {\sum }_{j = 1}^{m} {λ}_{j , θ} ( c ) {W}_{2}^{2} ( {z}_{j} , z ) \qquad ( 17 )$$

Considering an operational condition being a unique operational factor, and taking as example the temperature (c=T), the barycenter may be considered between two extreme conditions, i.e., two extreme values of the operational factor, and it may take the following form:

$${f}_{θ} ( T ) = {argmin}_{z} ( 1 - {λ}_{θ} ( T ) ) {W}_{2}^{2} ( {z}_{0} , z ) + {λ}_{θ} ( T ) {W}_{2}^{2} ( {z}_{1} , z ) \qquad ( 18 )$$

λ_{θ}(T) can be interpreted as the level of degradation according to the operational factor, and may be expressed as a function of the operational factor. Considering the example of temperature, lambda may be expressed as:

$$λ ( T ) = {a}_{0} - {a}_{1} exp ( {a}_{2} T )$$

In that case, the parameter θ=(a₀, a₁, a₂)

In order to estimate the parameter, said parameter is learned on the training database formed by the trained models obtained for the respective operational conditions, by finding θ* such that the average error of the prediction model, denoted:

$$\hat{R} ( θ ) = \frac{1}{K} {\sum }_{k = 1}^{K} {W}_{2}^{2} ( {f}_{θ} ( {c}_{k} ) , {z}_{k} ) \qquad ( 19 )$$

is minimized.

According to a second approach, hereinafter denoted “Fréchet regression,” the barycenter coordinates are determined as proposed in the Fréchet regression framework which generalizes the standard linear regression (Petersen, A., & Müller, H. G. (2019). Fréchet regression for random objects with Euclidean predictors.).

Considering a standard linear regression,

$$y = {β}_{0} + {β}_{1} {c}_{1} + … + {β}_{p} {c}_{p} \qquad ( 20 )$$

with data

$${( {c}_{i} , {y}_{i} )}_{i = 1}^{n} ,$$

an estimation \hat{β} of β=(β₀, . . . , βₚ) can be obtained as solution of the mean square problem, leading to the prediction ŷ(c_{*})=\hat{β}c_{*}. Importantly, these predictions can be rewritten as a linear combination of the observations:

$$\hat{y} ( c \text{*)} = {\sum }_{i = 1}^{n} {λ}_{i} ( c * ) {y}_{i} \qquad ( 21 )$$

with weights

$${λ}_{i} ( c \text{*)} = 1 + {( {c}_{i} - \overline{c} )}^{T} {\hat{\sum }}^{- 1} ( c * - \overline{c} ) \qquad ( 22 )$$

where

$$\overline{c} = {n}^{- 1} {\sum }_{i = 1}^{n} {c}_{i} \underline{and} \hat{\sum } = {n}^{- 1} {\sum }_{i = 1}^{n} ( {c}_{i} - \overline{c} ) ( {c}_{i} - \overline{c} ) .$$

Since, for a fixed input c, weights sum to 1, this weighted mean can be seen as a Euclidean barycenter with corresponding coordinates. By replacing the Euclidean barycenter by the Wasserstein barycenter, an explicit formula for the coordinates of the Wasserstein barycenter applied to operational conditions is obtained.

Further, to take into account the acceleration of the degradation, the standard linear regression provided above is replaced by a polynomial regression corresponding, for a unique operational factor c, to:

$$y = {β}_{0} + {β}_{1} c + … + {β}_{q} {c}^{q} \qquad ( 23 )$$

which in fact corresponds to a linear regression with c=(c, . . . , c^{q}) as inputs.

Then, to take into account interactions between a plurality of operational factors cᵢ, ranging from 1 to p, the above standard linear regression model may be written as:

$$y = {β}_{0} + {\sum }_{i = 1}^{p} {β}_{i} {c}_{i} + {\sum }_{i , j} {β}_{i , j} {c}_{i} {c}_{j} \qquad ( 24 )$$

where the first sum corresponds to the direct effects of an operational factor cᵢ and the second to the interaction effects between operational factors cᵢ, cⱼ.

Then, both polynomial and interaction terms can be used simultaneously. Considering two operational factors c₁ and c₂, the regression model is extended as follows:

$$y = {β}_{0} + {\sum }_{i}^{{q}_{1}} {β}_{1 , i} {c}_{1}^{i} + {\sum }_{i}^{{q}_{2}} {β}_{2 , i} {c}_{2}^{i} + {\sum }_{i , j}^{{q}_{1} {q}_{2}} {β}_{i , i} {c}_{1}^{i} {c}_{2}^{j} \qquad ( 25 )$$

with the first two sums, the polynomial direct effects of degree q₁ and q₂, and the last sum, the interaction between them.

Therefore, a polynomial version of the Fréchet regression, taking into account interactions between operational factors can be obtained using equation (22) above, with the extended inputs for c.

In embodiments, when the number of inputs is superior to K, E is no more invertible. To overcome this issue, the definition of X provided above may be replaced by:

$${λ}_{i} ( c \text{*)} = 1 + {( {c}_{i} - \overline{c} )}^{T} {\hat{\sum }}^{+} ( c * - \overline{c} ) \qquad ( 26 )$$

with ⁺ the Moore Penrose pseudo-inverse (one may refer to R. Penrose “A generalized inverse for matrices,” Mathematical proceedings of the Cambridge philosophical society, Vol 51. 3. Cambridge University Press, 1955, pp. 406-413)

The method then comprises a step 300 of implementing at least once the obtained prediction model for obtaining at least one additional predicted model characterizing the evolution of the state of health of a population of devices with duration of operation, for at least one additional operational condition, and in particular for at least one non-observed additional operational condition. This step may be implemented a plurality of times for covering a range of additional operational conditions.

Considering the prediction model computed above, step 300 may be performed by defining a value of λ(c*) corresponding to an additional operational condition c* in the definition of the prediction model in application of the formulas provided above for the definition of λ.

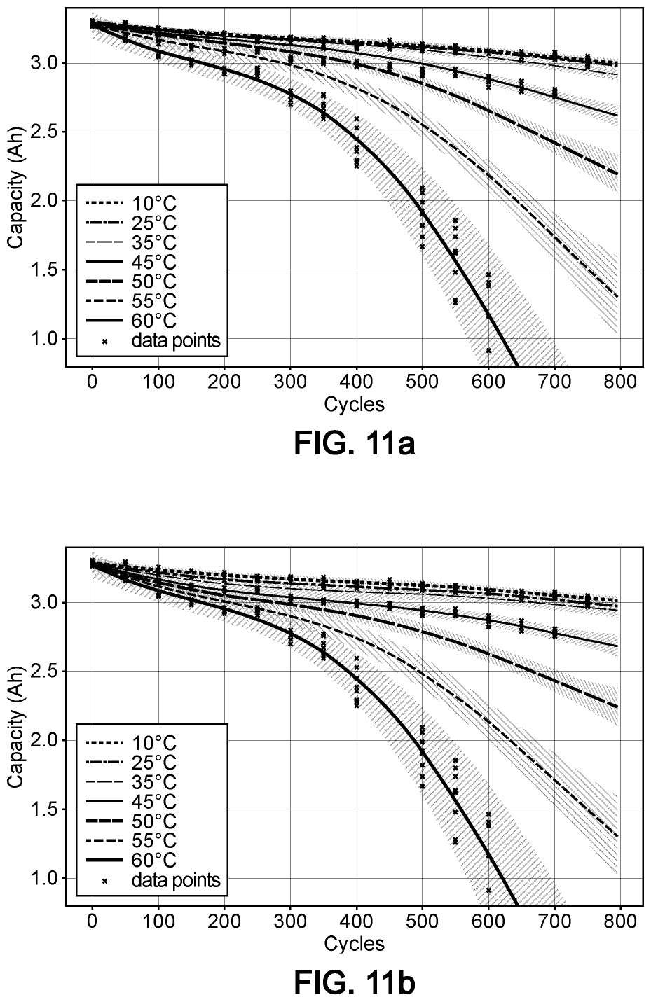

With reference to FIG. 11a, are shown in the same chart a plurality of predicted models describing degradation curves of batteries, for different values of temperatures, based on models obtained on training data for a plurality of different operational temperatures of 10° C., 25° C., 45° C. and 60° C., wherein the predicted models have been obtained by implementing the first approach described above. Predicted models are shown for unobserved temperatures of 35° C., 50° C. and 55° C. One can observe that the predictions respect monotony constraints either in time or in temperature as well as the acceleration of the degradation with temperature.

With reference to FIG. 11b, is displayed a chart of a plurality of predicted models describing degradation curves of batteries, for different values of temperatures, based on models trained for the same operational temperatures of 10° C., 25° C., 45° C. and 60° C., wherein the predicted models have been obtained for unobserved temperatures of 35° C., 50° C. and 55° C. according to the second approach described above.

One can notice that the predictions also respect monotonicities and accelerations with temperature. Further, the predicted models more adequately fits the data acquired for a temperature of operation of 45° C.

In Tables 1 and 2 below are shown respectively MAE and NLPD performance indicators computed between:
predicted degradation curves obtained for batteries at temperatures of 25° C. and 45° C., by application of the two approaches described above, and
actual, measured degradation curves for the same temperatures.

Regarding the second approach—Fréchet regression, results are indicated for both a linear regression and a polynomial regression.

The prediction of a degradation curve at a temperature of 25° C. is obtained using a prediction model obtained from trained models at temperatures of 10, 45, and 60° C. The prediction of a degradation curve at a temperature of 45° C. is obtained using a prediction model obtained from trained models at temperatures of 10, 25, and 45° C.

TABLE 1

| | | |
|---|---|---|
| Structured regression | Linear Fréchet | Polynomial Frechet |

MAE performance indicators

| | | | |
|---|---|---|---|
| 25° C. | 0.091 | 0.193 | 0.081 |
| 45° C. | 0.207 | 0.522 | 0.207 |

NLPD performance indicators

| | | | |
|---|---|---|---|
| 25° C. | 28.745 | 10.733 | 19.802 |
| 45° C. | 63.31 | 50.491 | 19.223 |

The models presented above—either trained models on data, or predicted models—may thus be used, to provide the mean evolution of state of health of the population of devices and associated uncertainty for a given duration of operation.

The additional steps 200, 300 presented above enable to predict a degradation trend of a population of devices, and the evolution of the variability of the population with respect to the average, for a new, unobserved operational condition.

In embodiments, these two elements may also be used to obtain an individual prediction for an individual device operating under said operational condition, when data is available on the state of health of the device for at least one, and preferably a plurality of durations of operation, and at said operational condition.

It is then possible to determine an individual normalized deviation of the state of health of the device with respect to the predicted trend for the population. Said individual normalized deviation may be obtained by subtracting, to the values of state of health of the device, the predicted mean trend of the population, and dividing it by the predicted inter-device variability, and fitting the predicted model on the obtained data. The fitted model then enables to provide individualized prediction for the device. From this, it is possible to determine a remaining useful life of the device.

The various embodiments described above can be combined to provide further embodiments. All of the patents, applications, and publications referred to in this specification and/or listed in the Application Data Sheet are incorporated herein by reference, in their entirety. Aspects of the embodiments can be modified, if necessary to employ concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. A computer-implemented method for characterizing an evolution of the state of health of a population of devices with duration of operation, the method comprising:
training a model on a database comprising, for each device among the population of devices, a value of duration of operation of the device and a corresponding state of health of the device, said model being a random process comprising at least a sum of:
a term representing an average evolution of the state of health of the population of devices with duration of operation; and
a term representing an inter-device variability of a degradation of the state of health at equal duration of operation, the variance of said term evolving with the duration of operation.

2. The method according to claim 1, wherein the term representing the inter-device variability is a non-linear combination of random processes.

3. The method according to claim 1, wherein the term representing the inter-device variability is a non-linear combination of Gaussian Processes.

4. The method according to claim 1, wherein the term representing the inter-device variability is a product of:
a first Gaussian Process corresponding to a deviation of a predicted quantity from the average, said first Gaussian Process having constant variance with duration of operation; and
a positive transform of a second Gaussian Process corresponding to an evolution of the deviation with the duration of operation.

5. The method according to claim 3, wherein said training comprises adding to the database data representative of a tendency, with duration of operation, of at least one term of the model.

6. The method according to claim 5, wherein said training comprises adding to the database data representative of a monotony or concavity, with duration of operation, of at least one term of the model.

7. The method according to claim 5, wherein the database comprises, for the population of devices, values of state of health corresponding to values of duration of operation that are below a maximum duration of operation, and the method further comprises inferring, from said training, a mean value and associated uncertainty of the state of health of devices of the population, for at least one duration of operation exceeding said maximum duration of operation.

8. A computer-implemented method for characterizing an evolution of the state of health of a population of devices with duration of operation and according to determined operational conditions, comprising:
implementing the method according to claim 1 at least two times and under at least two respective different operational conditions, to obtain respectively at least two trained models corresponding to each operational condition;
computing, from the trained models corresponding to the at least two different operational conditions, a prediction model configured to predict a model characterizing the evolution of the state of health of a population of devices with duration of operation, for a plurality of additional operational conditions; and
implementing the prediction model to obtain at least an additional predicted model characterizing the evolution of the state of health of the population of devices with duration of operation, for at least one additional operational condition.

9. The method according to claim 8, wherein an operational condition is defined by a fixed value of at least one operational factor.

10. The method according to claim 9, wherein the at least one operational factor comprises a temperature of operation.

11. The method according to claim 9, wherein the device is a battery and the at least one operational factor comprises at least one of a charge cutoff current, a charging rate, a discharging rate, a depth of discharge, or a current at which the constant voltage (CV) phase of a constant current-constant voltage (CC-CV) charge is stopped.

12. A method according to claim 8, wherein the prediction model is a conditional Wasserstein barycenter having coordinates that are the values of a function of the operational conditions.

13. The method according to claim 8, wherein the prediction model is a Fréchet regression.

14. The method according to claim 12, wherein the at least two different operational conditions correspond to different values of a single operational factor; and
wherein computing the prediction model comprises determining the function of the operational conditions by defining said function as a parametric function depending on a parameter that is learned on a database formed by a plurality of pairs comprising an operational condition and a trained model corresponding to that operational condition.

15. The method according to claim 8, further comprising determining, from a trained model or the predicted model, respectively, an expected lifetime of a device of a same model as the devices of the population.

16. The method according to claim 1, further comprising determining, from the trained model for a device belonging to the population, a value of state of health and associated uncertainty for a given duration of operation of the device.

17. The method according to claim 16, further comprising inferring from a mean value of the state of health and associated uncertainty for the given duration of operation of the device, and from an expected lifetime of the model of the device, a remaining useful life of the device and associated uncertainty.

18. The method according to claim 8, further comprising determining, from a trained model or the predicted model, respectively, and from data associated with a device comprising, for at least one duration of operation, a state of health of the device, a deviation of the device from a predicted mean trend of the population and inferring, from said deviation, at least one prediction of the evolution of the state of health of the device for at least one respective future duration of operation of the device.

19. The method according to claim 1, wherein the device is a battery or a fuel cell.

20. The method according to claim 1, further comprising determining; a mean value and associated uncertainty of the state of health of devices of the population; for at least one duration of operation.

21. The method according to claim 8, further comprising determining a mean value and associated uncertainty of the state of health of devices of the population for at least one duration of operation, wherein the mean value and associated uncertainty are further determined for at least one operational condition.

22. A non-transitory computer readable storage medium having stored thereon code instructions for implementing the method according to claim 1, when the code instructions are implemented by a computer.

23. A device for predicting a state of health of a battery, comprising a computer and a memory, the device being configured to implement the method according to claim 1.

24. A distributed computing system comprising a server storing a model trained by implementation of the method according to claim 1, and a battery management system or a fuel cell management system, wherein the battery management system or fuel cell management system is configured to:
receive a duration of operation of a battery or a fuel cell, respectively,
communicate said duration of operation to the server,
and the server is configured to obtain, from said duration of operation and by application of the model, an indicator comprising at least one of a state of health or remaining useful life of the battery or fuel cell, and return said indicator to the battery management or fuel cell management system, respectively.
